(19) United States
(12) Patent Application Publication
(10) Pub. No.: US 2009/0288942 A1
(43) Pub. Date: Nov. 26, 2009

(54) PARTICULATE CAPTURE IN A PLASMA TOOL

(76) Inventor: Scott Arthur Cummings, Colchester, VT (US)

Correspondence Address: SCHMEISER, OLSEN & WATTS, 22 CENTURY HILL DRIVE, SUITE 302, LATHAM, NY, 12110, US

(21) Appl. No.: 12/123,702

(22) Filed: May 20, 2008

(51) Int. Cl. C23C 14/34

(52) U.S. Cl. 204/192.11; 204/298.04

(57) ABSTRACT

A method and apparatus for increasing adhesion of particles ejected from a substrate being sputtered to interior surfaces of a vacuum chamber containing the substrate. The method includes: forming a viscous coating on a at least some regions of interior surfaces of the vacuum chamber, the viscous coating having a vapor pressure of no greater than 1/1000 of a nominal operating pressure of the vacuum chamber, the vapor pressure measured at a maximum operating temperature of the interior surfaces of the vacuum chamber that will be reached when the substrate is being bombarded by ions generated in and extracted from a plasma; and bombarding the substrate with the ions and capturing at least some of the ejected particles in the viscous coating.

### FIELD OF THE INVENTION

The present invention relates to the field of sputter cleaning and etching; more specifically, it relates to an apparatus and method for capture of particulates generated during plasma sputter cleaning and etching.

### BACKGROUND OF THE INVENTION

Plasma processes such as sputter cleaning and sputter etching can generate particulates that can contaminate the substrate being etched or cleaned leading to low yields. Accordingly, there exists a need in the art to mitigate the deficiencies and limitations described hereinabove.

### SUMMARY OF THE INVENTION

A first aspect of the present invention is a method for increasing adhesion of particles ejected from a substrate being sputtered to interior surfaces of a vacuum chamber containing the substrate, comprising: forming a viscous coating on a at least some regions of interior surfaces of the vacuum chamber, the viscous coating having a vapor pressure of no greater than 1/1000 of a nominal operating pressure of the vacuum chamber, the vapor pressure measured at a maximum operating temperature of the interior surfaces of the vacuum chamber that will be reached when the substrate is being bombarded by ions generated in and extracted from a plasma; and bombarding the substrate with the ions and capturing at least some of the ejected particles in the viscous coating.

A second aspect of the present invention is an apparatus, comprising: a vacuum chamber; means for generating a vacuum in the plasma chamber; a chuck for holding a substrate in the vacuum chamber; means for generating a plasma in the vacuum chamber; means for directing ions from the plasma to the substrate; and a viscous coating on a at least some regions of interior surfaces of the vacuum chamber, the viscous coating having a vapor pressure of no greater than 1/1000 of a nominal operating pressure of the vacuum chamber, the vapor pressure measured at a maximum operating temperature of the interior surfaces of the vacuum chamber that will be reached when the substrate is being bombarded by ions generated in and extracted from a plasma

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIG. 1 is a cross-sectional view of an exemplary sputter clean/etch tool on which the present invention may be practiced;

FIG. 2 is a cross-section of a portion of the sputter etch/clean tool after preparation according to the embodiments of the present invention; and

FIG. 3 is a cross-section of a portion of the sputter etch/clean tool after preparation illustrating operation of the embodiments of the present invention.

### DETAILED DESCRIPTION OF THE INVENTION

Sputter cleaning is a process where a substrate or a layer on a substrate is bombarded by ions generated in and extracted from a plasma in an effort to physically dislodge material on the surface of the substrate. Sputter etching is a process where a substrate is bombarded by ions generated in and extracted from a plasma in an effort to physically etch holes into the substrate or into a layer on the substrate where the substrate or layer is not protected by a patterned photomask. The term sputter tool is intended to cover tools designed for and/or running either sputter clean or sputter etch process.

An example of a sputter etch process is etching a dielectric or metal layer using a patterned photomask. An example of a sputter clean process is cleaning organic or inorganic contaminants from a surface either before or after other processes such as photolithography, etching, ion implantation, deposition or plating to give a few examples.

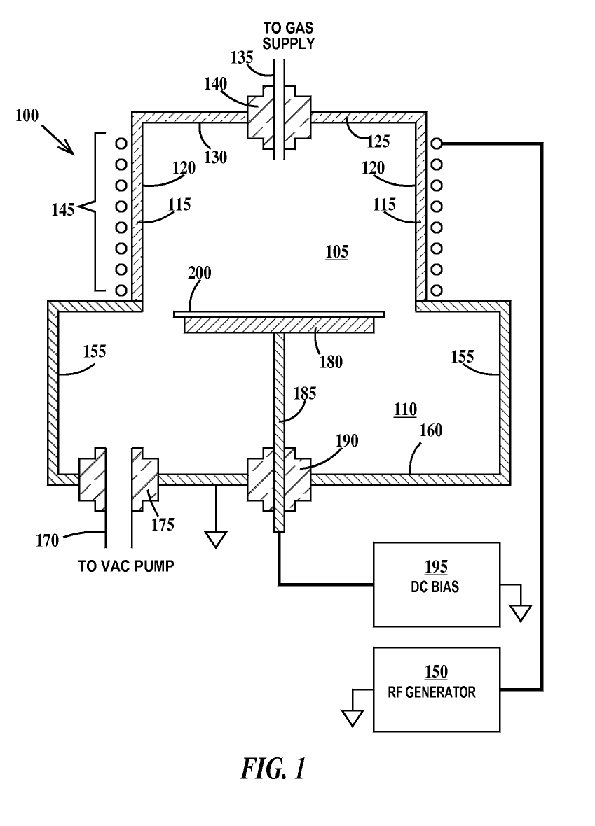

FIG. 1 is a cross-sectional view of an exemplary sputter clean/etch tool on which the present invention may be practiced. In FIG. 1, a sputter tool 100 includes an upper chamber 105 open to a lower chamber 110. Upper and lower chambers are hermetically attached to each other. In one example, the upper chamber may be formed from quartz. Access ports (not shown) may be provided to either or both of upper and lower process chambers 105 and 110.

Upper chamber 105 includes sidewalls 115 having an inner surface 120 and a top 125 having an inner surface 130. A gas inlet 135 is provided through top 125 through an insulated pass-through 140. An RF coil 145 is wrapped around the outside of upper chamber 105 and connected to a low-frequency RF (i.e., about 30 KHz to about 100 Mhz) generator 150.

Lower chamber 110 has sidewalls 155 and a bottom 160. A vacuum port 170 connected to a vacuum pump is provided through bottom 160 through an insulated pass-through 175. An electrically conductive substrate chuck 180 is held proximate to the opening between upper chamber 105 and lower chamber 110. Chuck 180 is held in place by an electrically conductive pedestal 185. Pedestal 185 is passes through an insulated pass through 190 and is electrically connected to a DC bias circuit 195. Chuck 180 is configured to hold a substrate 200. In one example, substrate 200 is a semiconductor wafer (i.e., a disk shaped substrate).

FIG. 2 is a cross-section of a portion of the sputter etch/clean tool after preparation according to the embodiments of the present invention. In FIG. 2, a viscous coating 205 has been formed on inner surfaces 120 and 130 of upper chamber 105. Viscous coating 205 advantageously consists of one or more viscous liquids having a high enough viscosity so as to not flow off the surfaces to which it is applied between application and use and has a low enough vapor pressure at the temperature of the surfaces at operation to which it is applied and at the pressure of the chamber so as not to volatilize away before or during the processing. A viscous liquid is defined as a liquid having a kinematic viscosity of greater than or equal to about 1000 centistokes (cST) at room temperature (i.e., 20° C.). In one example, viscous coating 205 advantageously comprises a liquid having a kinematic viscosity of greater than or equal to about 3500 cST at room temperature. Viscous coating 205 may be applied by spraying, brushing or spin coating. The coating liquid may be heated above room temperature during the application process.

Viscous coating 205 consists of one or more viscous liquids each having a vapor pressure no greater than about 1/1000 of the pressure of upper chamber 105 at a nominal operating pressure and at maximum inner surface temperature that will be reached during sputtering. In one example, viscous coating 205 consists of one or more viscous liquids each having a vapor pressure of about 4E-15 or less torr at room temperature. In one example, viscous coating 205 consists of one or more viscous liquids each having a vapor pressure of about 3E-7 or less at about 200° C.

In a preferred embodiment, viscous coating 205 comprises a viscous liquid having a vapor pressure of about 3E-7 torr or less at about 200° C. or less and a chamber pressure of about 4E-4 torr or less. In one example, viscous coating 205 comprises a perfluropolyether (PFPE). In one example, viscous coating 205 consists essentially of perfluropolyether (PFPE) as a mixture of materials could adversely effect the physical properties of the coating particularly vapor pressure. An example of a suitable PFPE is Kyrtox manufactured by DuPont. In one example, viscous coating 205 comprises a silicone oil. An example of a suitable silicone oil is Cumberland Vacuum CVP-705. In one example, viscous coating 205 comprises a polyphenyl ether oil. An example of a suitable polyphenyl ether oil is Cumberland Vacuum Santovac.

While the interior surfaces 120 and 130 of sidewalls 115 and top 125 have been coated with viscous coating 205, alternatively, only those surfaces most likely to be struck by ejected particle need be coated. For examples, only sidewalls 115 or regions of sidewalls 115 proximate to chuck 180 may be coated. Further, regions of interior surfaces of lower chamber 10 (see FIG. 1) may also be coated with viscous coating 205.

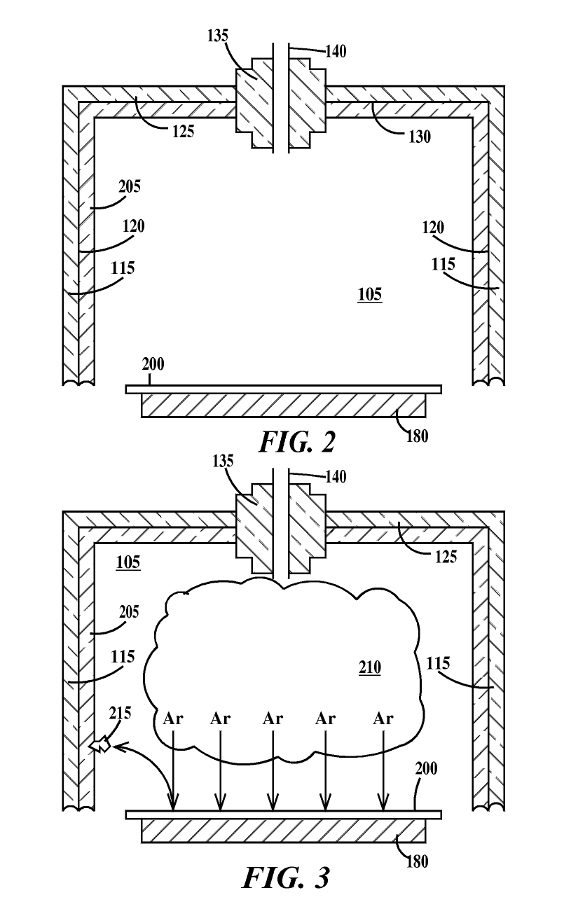

FIG. 3 is a cross-section of a portion of the sputter etch/clean tool after preparation illustrating operation of the embodiments of the present invention. In FIG. 3, a vacuum has been formed in upper chamber 105 and an argon plasma 210 struck. Because of the DC bias applied to chuck 180, argon ions are extracted from plasma 205 and strike wafer 200. An exemplary particle 215 is generated by the argon ions striking wafer 200 and the particle becomes trapped by viscous coating 205 instead of bouncing off sidewall 120 and landing back on wafer 200. It should be understood, that other gases besides argon may be used, (e.g., krypton and xenon).

Periodically, viscous coating 205 is removed and a new coating applied. In one example, viscous coating 205 is removed by ultrasonic hot water (i.e., greater than 50° C. water) cleaning with or without detergent. If detergent is used, a second hot water rinse is performed.

Thus the embodiments of the present invention provide a method reducing particulate contamination in a plasma clean/etch tool by increasing adhesion of ejected particles from the substrate being sputtered to the interior surfaces of the sputter chamber and an apparatus for plasma cleaning/etching that captures particulates generated during plasma cleaning/etching, preventing the particulates from contaminating the substrate being cleaned/etched.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A method for increasing adhesion of particles ejected from a substrate being sputtered to interior surfaces of a vacuum chamber containing said substrate, comprising:
forming a viscous coating on a at least some regions of interior surfaces of said vacuum chamber, said viscous coating having a vapor pressure of no greater than 1/1000 of a nominal operating pressure of said vacuum chamber, said vapor pressure measured at a maximum operating temperature of said interior surfaces of said vacuum chamber when said substrate is being bombarded by ions generated in and extracted from a plasma; and
bombarding said substrate with said ions and capturing at least some of said ejected particles in said viscous coating.

2. The method of claim 1, wherein said viscous coating has a kinematic viscosity greater than or equal to about 1000 cST at about 20° C.?

3. The method of claim 1, wherein said viscous coating has a vapor pressure of about 4E-15 or less at room temperature.

4. The method of claim 1, wherein said viscous coating has a vapor pressure of about 3E-7 or less at about 200° C.

5. The method of claim 1, wherein said viscous coating comprises a perfluropolyether.

6. The method of claim 1, wherein said viscous coating consists essentially of perfluropolyether.

7. The method of claim 1, wherein said viscous coating comprises a silicone oil.

8. The method of claim 1, wherein said viscous coating comprises polyphenyl ether.

9. The method of claim 1, wherein said viscous coating comprises two or more viscous liquids.

10. The method of claim 1, wherein said viscous coating is applied by spraying, brushing or spin coating.

11. The method of claim 1, wherein said viscous coating is applied at a temperature greater than room temperature.

12. An apparatus, comprising:
a vacuum chamber;
means for generating a vacuum in said plasma chamber;
a chuck for holding a substrate in said vacuum chamber;
means for generating a plasma in said vacuum chamber;
means for directing ions from said plasma to said substrate; and
a viscous coating on a at least some regions of interior surfaces of said vacuum chamber, said viscous coating having a vapor pressure of no greater than 1/1000 of a nominal operating pressure of said vacuum chamber, said vapor pressure measured at a maximum operating temperature of said interior surfaces of said vacuum chamber that will be reached when said substrate is being bombarded by ions generated in and extracted from a plasma.

13. The apparatus of claim 11, wherein said viscous coating has a kinematic viscosity greater than or equal to about 1000 cST at about 20° C.

14. The apparatus of claim 11, wherein said viscous coating has a vapor pressure of about 4E-15 or less at room temperature.

15. The apparatus of claim 11, wherein said viscous coating has a vapor pressure of about 3E-7 or less at about 200° C.

16. The apparatus of claim 11, wherein said viscous coating comprises a perfluropolyether.

17. The apparatus of claim 11, wherein said viscous coating consists essentially of perfluropolyether.

18. The apparatus of claim 11, wherein said viscous coating comprises a silicone oil.

19. The apparatus of claim 11, wherein said viscous coating comprises polyphenyl ether.

20. The apparatus of claim 11, wherein said viscous coating comprises two or more viscous liquids.
